(19) United States
(12) Patent Application Publication
(10) Pub. No.: US 2025/0271845 A1
(43) Pub. Date: Aug. 28, 2025

(54) Article Transport Facility

(71) Applicant: Daifuku Co., Ltd., Osaka-shi (JP)

(72) Inventors: Makoto Kono, Komaki-shi (JP); Tomoaki Nishikawa, Hinocho (JP)

(21) Appl. No.: 19/064,999

(22) Filed: Feb. 27, 2025

(30) Foreign Application Priority Data
Feb. 28, 2024 (JP) 2024-028830

(51) Int. Cl. G05B 19/418; H01L 21/677

(52) U.S. Cl. CPC G05B 19/41895; G05B 19/41865; H01L 21/67766; G05B 2219/31003; G05B 2219/31004

(57) ABSTRACT

In an article transport facility, the operational states of each of transport vehicles include a first state in which the transport vehicle is traveling to a transport destination being set to receive or transfer articles and a second state in which the transport destination is not set. A transport vehicle, among the transport vehicles, in the second state is a standby vehicle. A control system obtains, in determining a travel destination of the standby vehicle, information indicating a battery level of a power storage included in the standby vehicle. The control system determines the travel destination in a charging area or in a non-charging area in response to the battery level being greater than or equal to a set value and determines the travel destination in the charging area in response to the battery level being less than the set value.

### CROSS-REFERENCE TO RELATED APPLICATION

This application claims priority to Japanese Patent Application No. 2024-028830 filed Feb. 28, 2024, the disclosure of which is hereby incorporated by reference in its entirety.

### BACKGROUND OF THE INVENTION

### Field of the Invention

The present invention relates to an article transport facility including multiple transport vehicles that move along a travelable path to transport articles and a control system that controls the transport vehicles.

### Description of Related Art

An example of such an article transport facility is described in Japanese Unexamined Patent Application Publication No. 2012-38134 (JP 2012-38134). In the background described hereafter, reference signs in parentheses are the reference signs in JP 2012-38134. The article transport facility described in JP 2012-38134 includes overhead traveling vehicles (16) as transport vehicles that move along a travelable path to transport articles, and a ground controller (20) as a control system that controls the transport vehicles. Each overhead traveling vehicle (16) includes a secondary battery (28). A travel motor (60) and a transfer system motor (61) in the overhead traveling vehicle (16) are driven by power stored in the secondary battery (28) and, in sections with a non-contact feed line (14), by power from the non-contact feed line (14) (paragraph 0024). The ground controller (20) instructs an overhead traveling vehicle (16) having low remaining capacity of the secondary battery (28) to travel to a charging bay route (8) and recharge or to recharge in a straight section with a non-contact feed line (14) of routes (4, 6) (paragraph 0020).

A transport vehicle in an operational state in which the transport vehicle is traveling to a transport destination set to receive or transfer an article is referred to as an operating vehicle, and a transport vehicle in an operational state in which the transport destination is not set is referred to as a standby vehicle. A standby vehicle may be moved for an operation other than for recharging a power storage included in the standby vehicle. In moving a standby vehicle for an operation other than for recharging, the destination of the standby vehicle is to be set appropriately to allow the transport vehicle to properly transport an article when the standby vehicle becomes an operating vehicle after moving to a travel destination. However, in JP 2012-38134, recharging a transport vehicle with a low battery level at a location at which the transport vehicle can be recharged is described, but moving a standby vehicle for an operation other than for recharging is not described.

### SUMMARY OF THE INVENTION

One or more aspects are directed to setting a travel destination of a standby vehicle appropriately in moving the standby vehicle for an operation other than for recharging.

An article transport facility according to an aspect of the disclosure includes a plurality of transport vehicles that move along a travelable path to transport articles, and a control system that controls the plurality of transport vehicles. The travelable path includes a charging area in which a power feeder is disposed to supply electric power to the plurality of transport vehicles and a non-charging area in which no power feeder is disposed. Each of the plurality of transport vehicles includes a power storage, a power receiver that receives electric power from the power feeder, and a drive drivable by at least one of electric power stored in the power storage or electric power received by the power receiver. Operational states of each of the plurality of transport vehicles include a first state in which the transport vehicle is traveling to a transport destination being set to receive or transfer the articles and a second state in which the transport destination is not set. A transport vehicle, among the plurality of transport vehicles, in the second state is a standby vehicle. The control system obtains, in determining a travel destination of the standby vehicle, information indicating a battery level of the power storage included in the standby vehicle. The control system determines the travel destination in the charging area or in the non-charging area in response to the battery level being greater than or equal to a set value and determines the travel destination in the charging area in response to the battery level being less than the set value.

For example, a standby vehicle may be moved for an operation other than for recharging, such as for facilitating the movement of an operating vehicle (a transport vehicle in the first state) or for arranging multiple standby vehicles (transport vehicles in the second state) in a distributed manner to newly transport articles. This structure can determine, in moving a standby vehicle for such an operation other than for recharging, an appropriate travel destination of the standby vehicle based on the battery level of the standby vehicle. More specifically, when the battery level of the standby vehicle is high, the travel destination can be determined without being restricted by the charging area, with the standby vehicle less likely to have an insufficient battery level at the travel destination. When the battery level of the standby vehicle is low, the travel destination can be determined in the charging area in which the power storage can be recharged to reduce the likelihood that the standby vehicle has an insufficient battery level at the travel destination. This reduces, independently of the battery level of the standby vehicle, the likelihood that the standby vehicle that has moved to the travel destination has an insufficient battery level. Thus, when the standby vehicle becomes an operating vehicle after moving to the travel destination, the operating vehicle can transport an article appropriately. As described above, this structure can set, in moving a standby vehicle for an operation other than for recharging, a travel destination of the standby vehicle appropriately.

Further aspects and features of the article transport facility will be apparent from embodiments described below with reference to the drawings.

### BRIEF DESCRIPTION OF THE DRAWINGS

FIG. 1 is a diagram of an example layout of an article transport facility.

FIG. 2 is a side view of an example transport vehicle.

FIG. 3 is a front view of the example transport vehicle.

FIG. 4 is a control block diagram in an embodiment.

FIG. 5 is a diagram describing a push-out process.

FIG. 6 is a diagram describing a balancing process.

FIG. 7 is a diagram of a travelable path represented using nodes and links.

FIG. 8 is a diagram showing a result of finding a travel path when a cost adjustment process is not performed.

FIG. 9 is a diagram showing a result of finding the travel path when the cost adjustment process is performed.

### DESCRIPTION OF THE INVENTION

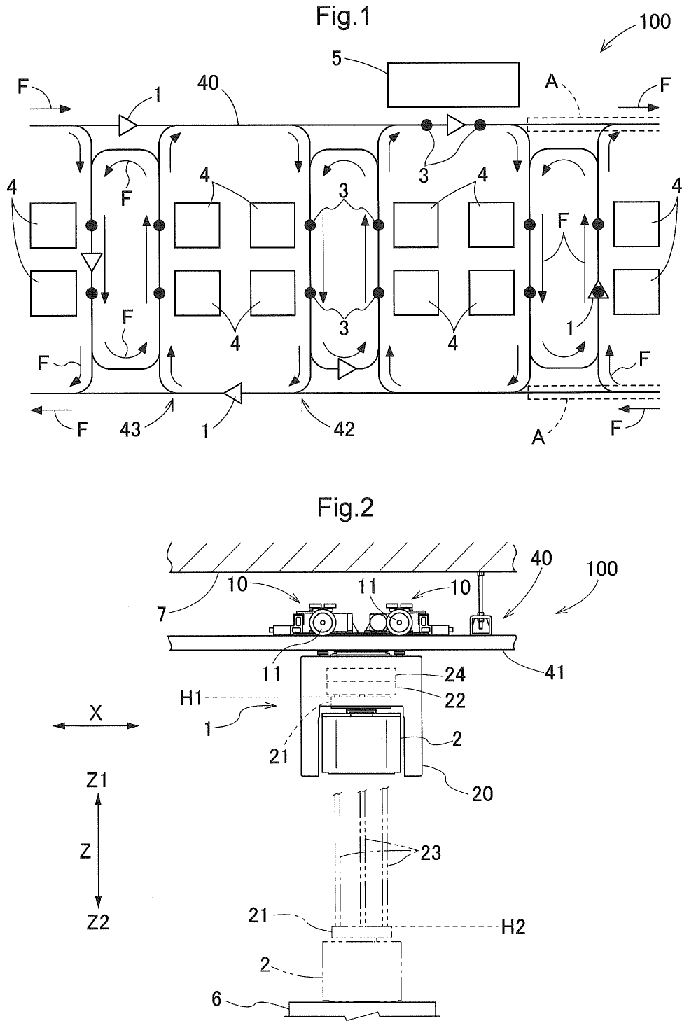

An article transport facility according to an embodiment will be described with reference to the drawings. As shown in FIGS. 1 and 4, an article transport facility 100 includes multiple transport vehicles 1 that move along a travelable path 40 to transport articles 2 (refer to FIG. 2) and a control system 30 that controls the transport vehicles 1. The various technical features of the control system 30 described herein are applicable to a method for controlling the transport vehicles 1 and a program for controlling the transport vehicles 1 (a program for causing a computer to function as the control system 30). The method, the program, and a storage medium (e.g., a computer-readable recording medium such as an optical disc or a flash memory) storing the program are also described herein. The articles 2 (refer to FIG. 2) are, for example, front opening unified pods (FOUPs) containing semiconductor wafers.

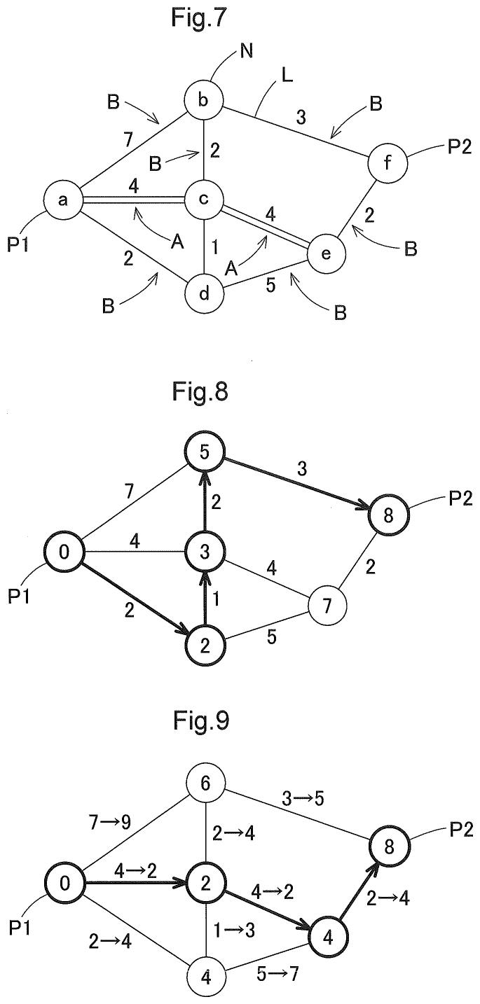

The travelable path 40 is a path along which the transport vehicles 1 are movable. As shown in FIG. 1, a forward direction F is defined for various parts of the travelable path 40. The transport vehicles 1 basically move along the various parts of the travelable path 40 in the forward direction F. The travelable path 40 includes junctions 42 at which multiple paths merge into a single path and branches 43 at which a single path branches into multiple paths. The travelable path 40 refers to a full portion of the path along which the transport vehicles 1 move. The travelable path 40 is a set of multiple paths (point-to-point paths connecting points). In the example shown in FIG. 7 (referred to later), nodes N correspond to the points, and links L correspond to the point-to-point paths. A travel path of each transport vehicle 1 is represented by a combination of multiple point-to-point paths.

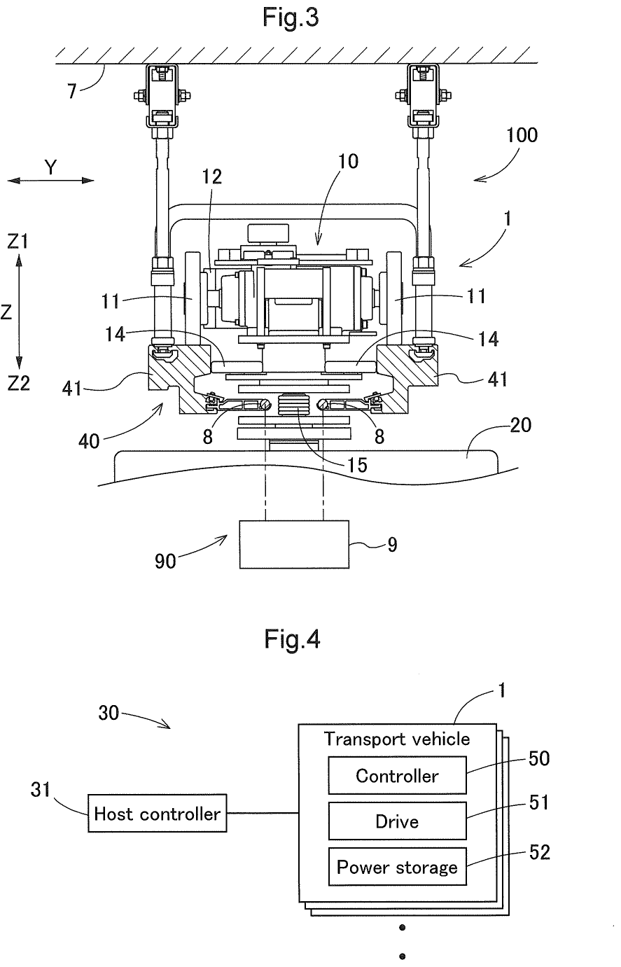

The travelable path 40 may be defined physically or virtually. In other words, the transport vehicles 1 may be tracked transport vehicles or trackless transport vehicles such as automated guided vehicles (AGVs). In the present embodiment, as shown in FIGS. 2 and 3, the travelable path 40 is physically defined with rails 41 (in this example, a pair of rails 41 spaced from each other in a lateral direction Y described later). The travelable path 40 may have a different structure and may be physically defined based on the shapes of aisles along which the transport vehicles 1 move. In this case, the travelable path 40 is physically defined by, for example, structures separating the aisles. Detectable members, such as magnetic tape, two-dimensional codes, or radio-frequency (RF) tags, that are detectable by the transport vehicles 1 may be installed on, for example, the floor surface to define the travelable path 40 virtually. In this case, the travelable path 40 is, for example, virtually defined along the detectable members or to connect the multiple detectable members.

As shown in FIGS. 2 and 3, the direction in which the transport vehicles 1 move and in which the travelable path 40 extends (the direction in which the rails 41 extend in this example) is referred to as a front-rear direction X, and the direction perpendicular to both the front-rear direction X and a vertical direction Z is referred to as the lateral direction Y. In the example shown in FIGS. 2 and 3, the rails 41 defining the travelable path 40 are hung from a ceiling 7. Thus, in this example, the transport vehicles 1 are ceiling-hung transport vehicles that move along the travelable path 40 disposed along the ceiling 7. The travelable path 40 may be disposed on, for example, the floor surface, rather than being disposed along the ceiling 7.

The transport vehicle 1 (a driverless transport vehicle in this example) shown in FIGS. 2 and 3 has the structure described below. The transport vehicle 1 includes travelers 10 and a body 20. Each traveler 10 includes travel wheels 11 that roll on travel surfaces of the rails 41, and a travel driver 12 (e.g., an electric motor such as a servo motor) that rotates the travel wheels 11. The travel wheels 11 are driven by the travel driver 12 to rotate, thus causing the traveler 10 to travel along the rails 41. This causes the transport vehicle 1 to move along the travelable path 40. In this example, the traveler 10 includes guide wheels 14 that roll on guide surfaces of the rails 41. The traveler 10 travels along the rails 41 with the guide wheels 14 in contact with and guided along the guide surfaces of the rails 41.

The travel driver 12 may be a set of drivers that drive multiple drive targets. For example, the traveler 10 may include a switcher that switches the traveling direction of the transport vehicle 1 at the branches 43 (refer to FIG. 1), and the travel driver 12 may drive the switcher in addition to the travel wheels 11. Although not described in detail, for example, the switcher switches the position of a guided portion included in the traveler 10 between a position at which the guided portion comes in contact with a guide rail extending along the travelable path 40 on a first side in the lateral direction Y and a position at which the guided portion comes in contact with the guide rail on a second side in the lateral direction Y.

The body 20 is connected to the travelers 10. In this example, the body 20 is disposed in a lower direction Z2 relative to the travelers 10. The body 20 includes a holder 21 that holds an article 2. The article 2 is transported by the transport vehicle 1 while being held by the holder 21. The body 20 includes a transfer driver (e.g., an electric motor such as a servo motor; not shown) for transferring an article 2 between the transport vehicle 1 and a transfer area (e.g., an article support 6 described later). The holder 21 is driven by the transfer driver and performs a holding operation of holding an article 2 and a releasing operation of releasing an article 2.

The transfer driver may be a set of drivers that drive multiple drive targets. In the example shown in FIG. 2, the body 20 includes a lifter 22 that lifts and lowers the holder 21 and a mover 24 that moves the holder 21 in the lateral direction Y. The transfer driver drives the lifter 22 and the mover 24 in addition to the holder 21. In this example, the lifter 22 lifts the holder 21 by winding wound members 23 (e.g., belts or wires) suspending the holder 21 on a rotator (e.g., a drum; not shown), and lowers the holder 21 by unwinding the wound members 23 from the rotator. In this example, the mover 24 moves the holder 21 supported by the lifter 22 in the lateral direction Y by moving the lifter 22 in the lateral direction Y. The body 20 may include a rotation device that rotates the holder 21 about a vertical axis parallel to the vertical direction Z, and the rotation device may be driven by the transfer driver.

As shown in FIG. 1, multiple stations 3 are arranged along the travelable path 40. Each station 3 includes the article support 6 (refer to FIG. 2) that supports an article 2. At each station 3, an article 2 is transferred between a transport vehicle 1 and the article support 6. The article support 6 is, for example, a load port of a processing device 4 that processes the articles 2 (or objects contained in the articles 2), a loading and unloading port of a storage device for storing the articles 2, or a storage shelf for storing the articles 2. Storing herein includes storing temporarily. A device for storing the articles 2 such as the storage device or the storage shelf described above is hereafter referred to as an article storage device 5.

When an article 2 is transferred between a transport vehicle 1 and an article support 6, the transport vehicle 1 travels to the station 3 including the article support 6. The transport vehicle 1 travels with the holder 21 at a reference height H1 (refer to FIG. 2). With the holder 21 at the reference height H1, the holder 21 and the article 2 held by the holder 21 are accommodated in the body 20. The reference height H1 is in an upper direction Z1 relative to a transfer height H2 (described later). After reaching the station 3, the transport vehicle 1 transfers the article 2 between the transport vehicle 1 and the article support 6. When the article support 6 is not immediately below the travelable path 40 and is at a position shifted from the travelable path 40 in the lateral direction Y, the transport vehicle 1 moves, with the mover 24, the holder 21 to a position immediately above the article support 6 in the lateral direction Y, and then transfers the article 2.

In transferring the article 2 from the transport vehicle 1 to the article support 6, a lowering operation, the releasing operation, and a lifting operation are performed in this order. In the lowering operation, the lifter 22 lowers the holder 21 holding the article 2 from the reference height H1 to the transfer height H2. The releasing operation is performed by the holder 21. In the lifting operation, the lifter 22 lifts the holder 21 holding no article 2 from the transfer height H2 to the reference height H1. The transfer height H2 (refer to FIG. 2) is set based on the height of the article support 6. In transferring the article 2 from the article support 6 to the transport vehicle 1, the lowering operation, the holding operation, and the lifting operation are performed in this order. In the lowering operation, the lifter 22 lowers the holder 21 holding no article 2 from the reference height H1 to the transfer height H2. The holding operation is performed by the holder 21. In the lifting operation, the lifter 22 lifts the holder 21 holding the article 2 from the transfer height H2 to the reference height H1.

As shown in FIGS. 3 and 4, each transport vehicle 1 includes a power storage 52, a power receiver 15 that receives power from a power feeder 90 (described later), and a drive 51 drivable by at least one of the power stored in the power storage 52 or the power received by the power receiver 15. The power storage 52 stores power. The power storage 52 can be recharged and discharged. The power storage 52 is, for example, a battery, a capacitor, or a combination of a battery and a capacitor. The power storage 52 includes a battery level sensor to detect a battery level. The battery level sensor includes, for example, one or both of a voltage sensor and a current sensor.

The drive 51 generates a driving force for causing the transport vehicle 1 to move along the travelable path 40. In the present embodiment, an article 2 is transferred between the transport vehicle 1 and a transfer area by the transport vehicle 1 moving the article 2. Thus, in the present embodiment, the drive 51 also generates a driving force for transferring an article 2 between the transport vehicle 1 and the transfer area. For example, in the transport vehicle 1 shown in FIGS. 2 and 3, the travel driver 12 generates the driving force for causing the transport vehicle 1 to move, and the transfer driver (not shown) generates the driving force for transferring an article 2. Thus, the drive 51 in the transport vehicle 1 includes both the travel driver 12 and the transfer driver. The drive 51 may include no transfer driver. In this case, for example, an article 2 is transferred between the transport vehicle 1 and the transfer area by a device disposed in the transfer area and moving the article 2.

As shown in FIG. 1, the travelable path 40 includes charging areas A in each of which the power feeder 90 (refer to FIG. 3) is disposed to supply power to the transport vehicles 1 and non-charging areas B in which no power feeder 90 is disposed. Although not shown in FIG. 1, the non-charging areas B are the areas other than the charging areas A in the travelable path 40 as shown in a simplified manner in FIG. 7 (referred to later). The power feeder 90 can supply power to at least one (in the present embodiment, both) of a transport vehicle 1 that is stopped or a transport vehicle 1 that is traveling. Power may be supplied to each transport vehicle 1 contactlessly or with contact in the charging areas A. The power received by the power receiver 15 in each charging area A is stored into the power storage 52 or used to drive the drive 51. In each charging area A, the drive 51 is driven by the power received by the power receiver 15. When the power received by the power receiver 15 is insufficient, the drive 51 is driven by both the power stored in the power storage 52 and the power received by the power receiver 15. In each non-charging area B, the drive 51 is driven by the power stored in the power storage 52. The drive 51 may be driven by the power stored in the power storage 52 when the power receiver 15 is not to receive power in the charging area A.

The power receiver 15 in the transport vehicle 1 shown in FIG. 3 receives power contactlessly through feed lines 8 installed along the travelable path 40 in the charging areas A. The power receiver 15 includes, for example, a pickup coil. In this example, the power feeder 90 includes the feed lines 8 and a power supply 9 that supplies power to the feed lines 8. In the pickup coil, alternating current power is induced by a magnetic field generated around the feed lines 8 receiving alternating current from the power supply 9. The alternating current power is converted to, for example, direct current power and supplied to the power storage 52 or to the drive 51.

As shown in FIG. 4, each transport vehicle 1 includes a controller 50 that controls the transport vehicle 1. The controller 50 and a host controller 31 (described later) each include, for example, an arithmetic processor such as a central processing unit (CPU) and a peripheral circuit such as a memory. The functions of the controller 50 and the host controller 31 are implemented by, for example, hardware such as an arithmetic processor and a program executable on the hardware operating in cooperation with each other. The controller 50 controls the drive 51. The controller 50 controls the drive 51 (e.g., the travel driver 12 described above) to cause the transport vehicle 1 to move along the travelable path 40. In the present embodiment, the controller 50 further controls the drive 51 (e.g., the transfer driver described above) to cause the transport vehicle 1 to transfer an article 2 between the transport vehicle 1 and the transfer area.

The control system 30 controls the multiple transport vehicles 1. In the present embodiment, as shown in FIG. 4, the control system 30 includes the host controller 31. The host controller 31 may be a set of multiple devices that can communicate with one another. The host controller 31 is connected to the controller 50 in each transport vehicle 1 to allow communication. The controller 50 controls the operation of the transport vehicle 1 in response to a command from the host controller 31. The host controller 31 assigns a task (e.g., a transport task described later) for transporting an article 2 to one of the multiple transport vehicles 1. The task may be generated by the host controller 31 or by another device that can communicate with the host controller 31. The host controller 31 then instructs the transport vehicle 1 to which the task is assigned to perform the task. The controller 50 in the transport vehicle 1 that has received the instruction controls the transport vehicle 1 to perform the task.

In the present embodiment, the control system 30 includes the host controller 31 and the controllers 50 (the controllers 50 in the transport vehicles 1 in this example) operating in cooperation. However, the control system 30 may include the host controller 31 alone. The control system 30 may include the controllers 50 in the transport vehicles 1 that are connected to allow communication between them and operate in cooperation with one another, without including the host controller 31.

The control system 30 (the host controller 31 in the present embodiment) tracks the current position of each of the multiple transport vehicles 1. In the present embodiment, each transport vehicle 1 identifies its current position, and the host controller 31 obtains information about the current position of the transport vehicle 1 from the transport vehicle 1. Although not described in detail, for example, detectable members (e.g., one-dimensional codes, two-dimensional codes, or RF tags) storing position information may be arranged at multiple positions along the travelable path 40, and the transport vehicle 1 may read the position information stored in a detectable member to identify its current position. The transport vehicle 1 identifies its current position based on, for example, the read position information and a travel distance after reading the position information. The transport vehicle 1 may identify its current position based on an output from a positioning device such as a global navigation satellite system (GNSS) receiver.

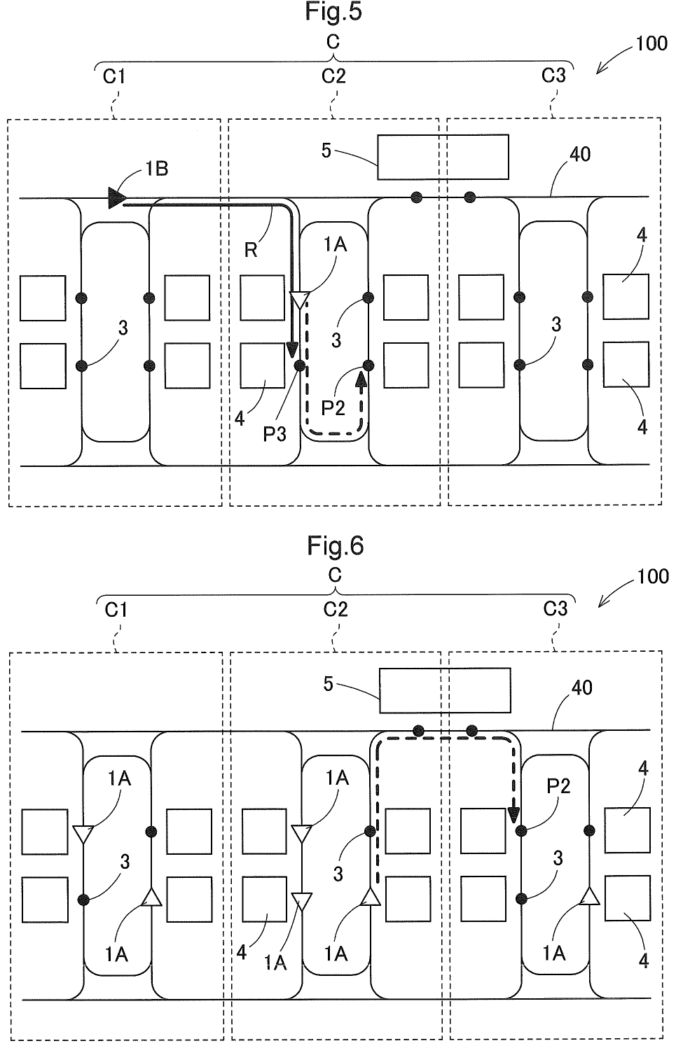

The control system 30 (the host controller 31 in the present embodiment) performs a travel path determination process, a power level obtaining process, a destination determination process, and a destination change process. The operational states of each transport vehicle 1 include a first state in which the transport vehicle 1 is traveling to a transport destination P3 (refer to FIG. 5) set to receive or transfer an article 2 and a second state in which the transport destination P3 is not set. In this example, a transport vehicle 1 in the first state is referred to as an operating vehicle 1B (refer to FIG. 5), and a transport vehicle 1 in the second state is referred to as a standby vehicle 1A (refer to FIGS. 5 and 6). The control system 30 performs the travel path determination process for standby vehicles 1A and operating vehicles 1B. The control system 30 performs the power level obtaining process, the destination determination process, and the destination change process for standby vehicles 1A.

The control system 30 assigns a transport task for transporting an article 2 from a receiving point to a transfer point to one of the multiple transport vehicles 1. The receiving point is a point (a source station 3) at which the article 2 is received and the transfer point is a point (a destination station 3) at which the article 2 is transferred. The transport task is preferentially assigned to, for example, a standby vehicle 1A that is near the receiving point. The standby vehicle 1A to which the transport task is assigned becomes an operating vehicle 1B. The operating vehicle 1B travels to the receiving point to receive the article 2 and then travels to the transfer point to transfer the article 2. When the operating vehicle 1B is moving to the receiving point, the receiving point is set as the transport destination P3. When the operating vehicle 1B is moving to the transfer point, the transfer point is set as the transport destination P3.

The travel path determination process is to determine the travel path along which a transport vehicle 1 moves. In the travel path determination process, one of multiple paths that are candidates for the travel path is determined to be the travel path. In the travel path determination process, a path with a short estimated travel time of the transport vehicle 1 is preferentially determined to be the travel path among the multiple paths that are the candidates for the travel path. For example, a path with the shortest estimated travel time of the transport vehicle 1 is determined to be the travel path. In the travel path determination process for a standby vehicle 1A, the control system 30 determines a travel path to a travel destination P2 (described later) as a travel path of the standby vehicle 1A. The control system 30 then controls the standby vehicle 1A to move to the travel destination P2 along the determined travel path. In the travel path determination process for an operating vehicle 1B, the control system 30 determines a travel path to the transport destination P3 as a travel path of the operating vehicle 1B. The control system 30 then controls the operating vehicle 1B to move to the transport destination P3 along the determined travel path. The details of the travel path determination process will be described later with reference to FIGS. 7 to 9.

The power level obtaining process is to obtain battery level information indicating the battery level (charge level) of the power storage 52 in a standby vehicle 1A. The battery level is represented by, for example, a ratio (percentage) of the remaining capacity to a full charge capacity. In this case, the battery level in a fully charged state is 100%, and the battery level in a fully discharged state is 0%. The battery level of the power storage 52 can be estimated based on, for example, the output voltage of the power storage 52, the integrated value of the recharge power level to the power storage 52 and the integrated value of the discharge power level from the power storage 52, or a combination of these. When the battery level of the power storage 52 is estimated by the controller 50 in the transport vehicle 1, the controller 50 transmits the battery level information indicating the estimated battery level to the host controller 31. When the battery level of the power storage 52 is estimated by the host controller 31, the host controller 31 obtains information to estimate the battery level of the power storage 52 (e.g., information about detection values from the battery level sensor described above) from the transport vehicle 1.

The destination determination process is to determine the travel destination P2 (refer to FIGS. 5 and 6) of a standby vehicle 1A. The control system 30 determines the travel destination P2 of a standby vehicle 1A in moving the standby vehicle 1A for, for example, an operation other than for recharging the power storage 52. A position to allow the operation for which the standby vehicle 1A is moved to be achieved (in other words, a position to allow the operation to be satisfied) is determined to be the travel destination P2 of the standby vehicle 1A. When the operation for which the standby vehicle 1A is moved can be achieved at multiple locations or positions (at multiple locations in the charging areas A for the battery level being less than a first set value described later), for example, a location that allows a cost of the travel path from a current location P1 of the standby vehicle 1A to the location to be minimum is determined to be the travel destination P2 among the multiple locations. The cost will be described later. The travel destination P2 determined through the destination determination process is then set in the standby vehicle 1A, and a travel path to the travel destination P2 set in the standby vehicle 1A is determined through the travel path determination process. Although each station 3 can serve as either the travel destination P2 or the transport destination P3, the travel destination P2 differs from the transport destination P3 in that the travel destination P2 is not set to receive nor transfer an article 2.

In determining the travel destination P2 of a standby vehicle 1A in the destination determination process, the control system 30 obtains the battery level information indicating the battery level of the power storage 52 in the standby vehicle 1A through the power level obtaining process. In response to the battery level of the standby vehicle 1A being greater than or equal to the first set value, the control system 30 determines the travel destination P2 of the standby vehicle 1A in a charging area A or in a non-charging area B. In response to the battery level of the standby vehicle 1A being less than the first set value, the control system 30 determines the travel destination P2 of the standby vehicle 1A in a charging area A. In other words, a position in a charging area A is determined to be the travel destination P2 in this case. The first set value may be the same for a full portion of the travelable path 40, but may be set to be different for each area. For example, when the ratio of the charging area A is different for each of divisional areas defined by dividing the full portion of the travelable path 40 into multiple areas, the first set value can be set to be, for each divisional area, greater for a lower ratio of the charging area A in the divisional area. In this case, the first set value set for the divisional area to which the standby vehicle 1A moves is used in the destination determination process. In the present embodiment, the first set value corresponds to a set value.

In the present embodiment, the control system 30 determines the travel destination P2 of the standby vehicle 1A for at least one (both in this example) of a push-out process or a balancing process. In other words, the operation other than for recharging the power storage 52 described above includes at least one of the push-out process or the balancing process. In FIGS. 5 and 6 referred to below, the thick dashed arrows each indicate the travel path of the standby vehicle 1A to the determined travel destination P2. In FIGS. 5 and 6, the charging areas A and the non-charging areas B are not shown.

As shown in FIG. 5, the push-out process moves any standby vehicle 1A on the travel path (hereafter referred to as a target path R) of an operating vehicle 1B out of the target path R. The operation for which the standby vehicle 1A is moved in the push-out process is to facilitate the movement of the operating vehicle 1B. Thus, a position (a station 3 in this example) out of the target path R to allow the operation to be achieved is determined to be the travel destination P2 of the standby vehicle 1A. In response to the battery level of the standby vehicle 1A being greater than or equal to the first set value, a point outside the target path R in a charging area A or in a non-charging area B is determined to be the travel destination P2 of the standby vehicle 1A. In response to the battery level of the standby vehicle 1A being less than the first set value, a point outside the target path R in a charging area A is determined to be the travel destination P2 of the standby vehicle 1A. In the example shown in FIG. 5, a position in a control area C in which the standby vehicle 1A is positioned is determined to be the travel destination P2. The control area C will be described later. In the present embodiment, as described above, the control system 30 determines, for any standby vehicle 1A on the target path R, the travel destination P2 of the standby vehicle 1A.

The balancing process is performed when the control system 30 manages the transport vehicles 1 for each of control areas C defined by dividing the full portion of the travelable path 40 into multiple areas, as shown in FIG. 6. The control areas C are defined by, for example, an operator. FIG. 6 shows three control areas C that are a first control area C1, a second control area C2, and a third control area C3. The balancing process moves a standby vehicle 1A to adjust the number of standby vehicles 1A in each of the multiple control areas C to be within a range set for the control area C. The range is hereafter referred to as a vehicle count range. The vehicle count range is preset by, for example, the operator. A standby vehicle 1A with a battery level being less than a set value set lower than the first set value may not be counted as a standby vehicle 1A in a control area C and may be excluded from the balancing process.

The vehicle count range may include a single specific vehicle alone. The vehicle count range may be set to be the same for the multiple control areas C or may be set individually for each of the control areas C. In FIG. 6, the same vehicle count range (more specifically, a range with a lower limit of two vehicles or a range including two vehicles alone) is set for the multiple control areas C. In this case, one standby vehicle 1A is moved from the second control area C2 to the third control area C3 through the balancing process. This adjusts the number of standby vehicles 1A in each of the three control areas C to be two that is within the vehicle count range set for each of the control areas C.

A standby vehicle 1A is moved in the balancing process for an operation of arranging the multiple standby vehicles 1A in a distributed manner for any new transport tasks. Thus, for example, a different vehicle count range may be set for each of the control areas C based on the frequency of transport tasks in the control area C. For example, for a control area C including a station 3 that serves as a receiving point of an article 2 more frequently than the other stations 3, a vehicle count range may be set with a lower limit greater than the lower limits of the vehicle count ranges set for the other control areas C.

In the balancing process, a position (a station 3 in this example) to allow the operation described above to be achieved is determined to be the travel destination P2 of a standby vehicle 1A. In response to the battery level of the standby vehicle 1A being greater than or equal to the first set value, the travel destination P2 is determined in a charging area A or in a non-charging area B. In response to the battery level of the standby vehicle 1A being less than the first set value, the travel destination P2 is determined in a charging area A. The first set value used in the balancing process may be the same as or different from the first set value used in the push-out process. In the present embodiment, as described above, the control system 30 determines the travel destination P2 of a standby vehicle 1A to adjust the number of standby vehicles 1A in each of the multiple control areas C defined by dividing the full portion of the travelable path 40 to be within a range set for the control area C.

In the present embodiment, in response to the battery level of a standby vehicle 1A being less than the first set value while the standby vehicle 1A is moving to the travel destination P2 in a non-charging area B, the control system 30 performs the destination change process of changing the travel destination P2 of the standby vehicle 1A to a position in a charging area A. For example, the travel destination P2 is changed to a position (a station 3 in this example) in the charging area A closest to the current position of the standby vehicle 1A. In the destination change process, the control system 30 determines a travel path to the travel destination P2 that has been changed through the travel path determination process.

In response to the battery level of a standby vehicle 1A being less than a set value (e.g., the first set value) while the standby vehicle 1A is moving to the travel destination P2 in a non-charging area B, the control system 30 may cause the standby vehicle 1A to operate in a power-saving mode in which less power is consumed than in a normal mode. The normal mode causes the standby vehicle 1A to operate without limiting the acceleration and the maximum speed (more specifically, with permission to reach up to predetermined upper limits of the acceleration and the maximum speed). The power-saving mode causes the standby vehicle 1A to operate with at least one of the acceleration or the maximum speed (e.g., with the acceleration alone) being limited (more specifically, limited to less than or equal to a value, the value being less than the corresponding upper limit described above).

In the present embodiment, the control system 30 determines, in the travel path determination process, the travel path of a transport vehicle 1 using a cost (weight) that is a value derived from factors affecting the travel time of the transport vehicle 1 and that is higher for a longer travel time. The control system 30 preferentially determines, as the travel path, a path with a lower cost among multiple paths. The cost corresponds to an estimated travel time. For example, in the travel path determination process, a travel path is found based on a pathfinding algorithm that can find a path with a minimum cost, such as Dijkstra's algorithm. A path with a minimum cost can thus be determined to be the travel path.

The factors affecting the travel time of the transport vehicle 1 include, for example, the distance of a path, the structures of a path, and a congestion level of a path (e.g., the length of congestion and the number of other transport vehicles 1 on the path). The above cost is set to be higher for a longer travel time of the transport vehicle 1 for such factors. For example, the above cost may include at least one of a distance cost, a structure cost, a congestion cost, or an other-vehicles cost. Including herein refers to including as an element to derive the cost. The cost is thus derived based on at least one of the distance cost, the structure cost, the congestion cost, or the other-vehicles cost. The cost can be derived by, for example, adding element costs, multiplying the element costs, or a combination of these, where the element costs are the distance cost, the structure cost, the congestion cost, and the other-vehicles cost.

The distance cost is higher for a greater distance by which the transport vehicle 1 moves. The distance cost can be determined based on the distance of a path, and can be set to, for example, a value obtained by multiplying the distance by a coefficient. The structure cost is higher for a slower possible moving speed (e.g., the maximum speed) of the transport vehicle 1 based on the structures of the travelable path 40. The structures of the travelable path 40 refer to structures that affect the moving speed of the transport vehicle 1, such as the junctions 42, the branches 43, the lifter (the lifter that lifts and lowers the transport vehicle 1 along a path along which the transport vehicle 1 is lifted and lowered), and curves. The structure cost can be determined based on the possible moving speed of the transport vehicle 1 at each structure, and can be set to, for example, a value obtained by multiplying the reciprocal of the possible moving speed by a coefficient.

The congestion cost is higher for longer congestion on a path (the travel path of the transport vehicle 1), a greater number of transport vehicles 1 involved in the congestion on the path, or both. Congestion can be defined as a state in which, when each of the transport vehicles 1 includes a collision avoidance sensor that detects another transport vehicle 1 in front of the transport vehicle 1, a transport vehicle 1 is stopped for more than a set time period with the collision avoidance sensor detecting another transport vehicle 1. In this case, the number of transport vehicles 1 that are stopped for more than the set time period is the number of transport vehicles 1 involved in the congestion. When the congestion cost is determined based on the number of transport vehicles 1 involved in the congestion on the path, for example, the congestion cost can be set to a value obtained by multiplying the number of transport vehicles 1 involved in the congestion by a coefficient. When the congestion cost is determined based on the length of the congestion on the path, for example, the congestion cost can be set to a value obtained by multiplying the length of the congestion by a coefficient. The other-vehicles cost is higher for a greater number of other transport vehicles 1 on a path (the travel path of the transport vehicle 1). In the present embodiment, the other transport vehicles 1 may be moving or stopped. The other-vehicles cost can be determined based on the number of other transport vehicles 1 on the path, and can be set to, for example, a value obtained by multiplying the number of other transport vehicles 1 on the path by a coefficient. The length of the congestion on the path, the number of transport vehicles 1 involved in the congestion on the path, and the number of other transport vehicles 1 on the path may be values (actual values) at the time of the travel path determination process being performed or estimated values at the time when the transport vehicle 1 reaches the path. The length of the congestion on the path, the number of transport vehicles 1 involved in the congestion on the path, and the number of other transport vehicles 1 on the path may be statistics based on past records.

In the present embodiment, the control system 30 performs, in determining the travel path of a standby vehicle 1A, a cost adjustment process in response to the battery level of the standby vehicle 1A being less than a second set value. The second set value is set to the same value as the first set value or a value different from the first set value (a value greater or less than the first set value). For example, when the battery level has a small margin, the second set value may be set lower than the first set value to avoid the possibility that the battery level is insufficient unless measures are taken for the path in addition to for the travel destination P2. The cost adjustment process includes at least one of a process of increasing the cost of a path through a non-charging area B to be higher than the cost for the battery level of the standby vehicle 1A being greater than or equal to the second set value or a process of reducing the cost of a path through a charging area A to be lower than the cost for the battery level of the standby vehicle 1A being greater than or equal to the second set value. The process of increasing the cost of a path through a non-charging area B involves, for example, increasing the cost of a link L in a non-charging area B or increasing the cost of a node N at the entrance of a non-charging area B. The process of reducing the cost of a path through a charging area A involves, for example, reducing the cost of a link L in a charging area A or reducing the cost of a node N at the entrance of a charging area A. The node N and the link L will be described later.

The travel path determination process in the present embodiment will now be described with reference to FIGS. 7 to 9. In this example, the travel path of a standby vehicle 1A (the travel path from the current location P1 to the travel destination P2) is found based on a pathfinding algorithm that can find a path with a minimum cost. Although a path starting from the current location P1 is to be found in the example below, a path starting from the travel destination P2 or a path starting from each of the current location P1 and the travel destination P2 can also be found.

In FIGS. 7 to 9, the travelable path 40 is represented using the nodes N and the links L connecting the nodes N. Each node N corresponds to a specific point such as a junction 42 or a branch 43 (refer to FIG. 1). Each link L corresponds to a point-to-point path connecting specific points. In the travel path determination process, the control system 30 sequentially connects links L to find a path. In FIG. 7, the double lines indicate the links L in the charging areas A, and the single lines indicate the links L in the non-charging areas B. Hereafter, to distinguish the multiple nodes N from one another, each node Nis followed by an alphabet, in parentheses, that is indicated in the circle representing the node N in FIG. 7. For example, a node N(a) represents the node N indicated with a. In this example, the node N(a) is the current location P1 of a standby vehicle 1A, and a node N(f) is the travel destination P2 of the standby vehicle 1A. In FIGS. 8 and 9, the alphabets to distinguish the nodes N from one another are not shown.

In FIGS. 7 to 9, each of the links L is denoted with a numerical value indicating a cost (link cost) that is the weight of the link L. The cost of a link L is the cost described above (the value derived from the factors affecting the travel time of a transport vehicle 1 and that is higher for a longer travel time) and is set for each of the links L. In other words, the cost of a link L corresponds to an estimated time taken to pass through the link L. The control system 30 derives the cost of a travel path based on the sum of the costs of the links L included in the travel path. In the present embodiment, the cost of a travel path is expressed as the sum of the costs of the links L included in the travel path. In this example, costs are not set for the nodes N. However, when costs are also set for the nodes N, the control system 30 derives the cost of a travel path based on the sum of the costs of the links L included in the travel path and on the sum of the costs of the nodes N included in the travel path. In this case, the cost of the travel path is expressed as, for example, the sum of the costs of the links L and the nodes N included in the travel path.

FIG. 8 shows a result of finding a travel path when the cost adjustment process described above is not performed. The number indicated on each node N indicates the cost of a path with a minimum cost from the node N(a) to the node N. In the example shown in FIG. 8, a path extending from the node N(a) to the Node N(f) through the node N(d), the node N(c), and the node N(b) in this order as indicated by the thick arrows is found as a path from the current location P1 to the travel destination P2 with a minimum cost. This path is determined to be the travel path.

FIG. 9 shows a result of finding the travel path when the cost adjustment process described above is performed. In this example, the process of increasing the costs of the paths through the non-charging areas B and the process of reducing the costs of paths through the charging areas A are both performed as the cost adjustment process. More specifically, the costs of the links L in the non-charging areas B are increased by two, and the costs of the links L in the charging areas A are reduced by two, as compared with the example in FIG. 8. Thus, in the example shown in FIG. 9, a path extending from the node N(a) to the Node N(f) through the node N(c) and the node N(e) in this order as indicated by the thick arrows is found as a path from the current location P1 to the travel destination P2 with a minimum cost. This path is determined to be the travel path. The comparison between FIGS. 8 and 9 reveals that a path through the charging areas A (refer to FIG. 7) is more likely to be determined to be the travel path by performing the cost adjustment process as shown in FIG. 9.

### Other Embodiments

(1) In the above embodiment, in response to the battery level of a standby vehicle 1A being less than the first set value while the standby vehicle 1A is moving to the travel destination P2 in a non-charging area B, the control system 30 performs the destination change process. In some embodiments, for example, the control system 30 may perform the destination change process in response to the battery level of a standby vehicle 1A being less than a third set value set to a value different from the first set value (e.g., a value less than the first set value) while the standby vehicle 1A is moving to the travel destination P2 in a non-charging area B. The third set value may be the same as or different from the second set value. The control system 30 may not perform the destination change process.

(2) In the above embodiment, the control system 30 performs, in determining the travel path of a standby vehicle 1A, the cost adjustment process in response to the battery level of the standby vehicle 1A being less than the second set value. In some embodiments, the control system 30 may not perform the cost adjustment process.

(3) The structure described in each of the above embodiments may be combined with any other structures described in the other embodiments unless any contradiction arises. This also applies to combinations of the embodiments described as other embodiments. The embodiments described herein are merely illustrative in all aspects and may be modified variously as appropriate without departing from the spirit and scope of the disclosure.

### Overview of Present Embodiment

An overview of the article transport facility according to the embodiments described above is provided below.

An article transport facility includes a plurality of transport vehicles that move along a travelable path to transport articles, and a control system that controls the plurality of transport vehicles. The travelable path includes a charging area in which a power feeder is disposed to supply electric power to the plurality of transport vehicles and a non-charging area in which no power feeder is disposed. Each of the plurality of transport vehicles includes a power storage, a power receiver that receives electric power from the power feeder, and a drive drivable by at least one of electric power stored in the power storage or electric power received by the power receiver. Operational states of each of the plurality of transport vehicles include a first state in which the transport vehicle is traveling to a transport destination being set to receive or transfer the articles and a second state in which the transport destination is not set. A transport vehicle, among the plurality of transport vehicles, in the second state is a standby vehicle. The control system obtains, in determining a travel destination of the standby vehicle, information indicating a battery level of the power storage included in the standby vehicle. The control system determines the travel destination in the charging area or in the non-charging area in response to the battery level being greater than or equal to a set value and determines the travel destination in the charging area in response to the battery level being less than the set value.

For example, a standby vehicle may be moved for an operation other than for recharging, such as for facilitating the movement of an operating vehicle (a transport vehicle in the first state) or for arranging multiple standby vehicles (transport vehicles in the second state) in a distributed manner to newly transport articles. This structure can determine, in moving a standby vehicle for such an operation other than for recharging, an appropriate travel destination of the standby vehicle based on the battery level of the standby vehicle. More specifically, when the battery level of the standby vehicle is high, the travel destination can be determined without being restricted by the charging area, with the standby vehicle less likely to have an insufficient battery level at the travel destination. When the battery level of the standby vehicle is low, the travel destination can be determined in the charging area in which the power storage can be recharged to reduce the likelihood that the standby vehicle has an insufficient battery level at the travel destination. This reduces, independently of the battery level of the standby vehicle, the likelihood that the standby vehicle that has moved to the travel destination has an insufficient battery level. Thus, when the standby vehicle becomes an operating vehicle after moving to the travel destination, the operating vehicle can transport an article appropriately. As described above, this structure can set, in moving a standby vehicle for an operation other than for recharging, a travel destination of the standby vehicle appropriately.

The control system may preferentially select from among a plurality of paths a travel path of a transport vehicle of the plurality of transport vehicles for which travel path a cost is low, the cost being a value derived from a factor affecting a travel time of the transport vehicle and being higher for a longer travel time of the transport vehicle. The control system may perform, in determining a travel path of the standby vehicle, a cost adjustment process in response to the battery level of the standby vehicle being less than a second set value. The cost adjustment process may include at least one of causing the cost of a path through the non-charging area to be higher than in a case of the battery level of the standby vehicle being greater than or equal to the second set value or causing the cost of a path through the charging area to be lower than in a case of the battery level of the standby vehicle being greater than or equal to the second set value.

This structure can also determine the travel path to the travel destination appropriately based on the battery level of the standby vehicle, in addition to the travel destination of the standby vehicle. In other words, when the battery level of the standby vehicle is low, a path through the charging area is more likely to be determined to be the travel path. This reduces the likelihood that the standby vehicle has an insufficient battery level while moving to the travel destination.

In the above structure, the cost may include at least one of a distance cost being higher for a greater distance by which the transport vehicle travels, a structure cost being higher for a slower possible moving speed of the transport vehicle based on a structure of the travelable path, a congestion cost being higher for longer congestion on the travel path of the transport vehicle, a greater number of transport vehicles involved in congestion on the travel path of the transport vehicle, or both, or an other-vehicles cost being higher for a greater number of other transport vehicles on the travel path of the transport vehicle.

This structure increases the accuracy of the cost that is the value derived from the factor affecting the travel time of the transport vehicle and that is higher for a longer travel time as well as the accuracy of appropriateness of the travel path determined based on the cost. Thus, a more appropriate travel path is determined to be the travel path of a transport vehicle easily.

In the article transport facility with each of the above structures, a transport vehicle, among the plurality of transport vehicles, in the first state may be an operating vehicle, and the control system may determine the travel destination of the standby vehicle on a travel path of the operating vehicle.

This structure reduces the likelihood that the standby vehicle obstructs the movement of the operating vehicle moving to transport an article, thus facilitating the movement of the operating vehicle. This easily increases the transport efficiency of articles in the article transport facility. The technique according to one or more embodiments of the disclosure determines, in moving a standby vehicle for such an operation, an appropriate travel destination based on the battery level of the standby vehicle as described above, thus reducing the likelihood that the standby vehicle that has moved to the travel destination has an insufficient battery level.

The control system may determine the travel destination of the standby vehicle in such a manner as to adjust the number of standby vehicles in each of a plurality of control areas defined by dividing a full portion of the travelable path so that the number of standby vehicles falls within a range set for the control area.

In this structure, multiple standby vehicles can be arranged in a distributed manner for any new tasks of transporting articles. This easily increases the transport efficiency of articles in the article transport facility. The technique according to one or more embodiments of the disclosure determines, in moving a standby vehicle for such an operation, an appropriate travel destination based on the battery level of the standby vehicle as described above, thus reducing the likelihood that the standby vehicle that has moved to the travel destination has an insufficient battery level.

In response to the battery level of the standby vehicle being less than the set value while the standby vehicle is traveling to the travel destination in the non-charging area, the control system may perform a destination change process of changing the travel destination of the standby vehicle to a position in the charging area.

In this structure, when a standby vehicle has a battery level greater than the set value at the time of determination of the travel destination and then has a battery level lower than the set value resulting from power consumption while moving, the standby vehicle can have the power storage recharged at the travel destination through the destination change process. This reduces the likelihood that the standby vehicle that has moved to the travel destination has an insufficient battery level.

The article transport facility according to one or more embodiments of the disclosure may produce at least one of the effects described above.

What is claimed is:

1. An article transport facility, comprising:
a plurality of transport vehicles configured to move along a travelable path to transport articles; and
a control system configured to control the plurality of transport vehicles, and
wherein:
the travelable path comprises a charging area in which a power feeder is disposed to supply electric power to the plurality of transport vehicles and a non-charging area in which no power feeder is disposed,
each of the plurality of transport vehicles comprises a power storage, a power receiver configured to receive electric power from the power feeder, and a drive drivable by at least one of electric power stored in the power storage or electric power received by the power receiver,
operational states of each of the plurality of transport vehicles comprise a first state in which the transport vehicle is traveling to a transport destination is set to receive or transfer the articles and a second state in which the transport destination is not set,
a transport vehicle, among the plurality of transport vehicles, in the second state is a standby vehicle,
the control system is configured to obtain, in determining a travel destination of the standby vehicle, information indicating a battery level of the power storage included in the standby vehicle, and
the control system is configured to determine the travel destination in the charging area or in the non-charging area in response to the battery level being greater than or equal to a set value and determine the travel destination in the charging area in response to the battery level being less than the set value.

2. The article transport facility according to claim 1, wherein:
the control system preferentially selects from among a plurality of paths a travel path of a transport vehicle of the plurality of transport vehicles for which travel path a cost is low, the cost is a value derived from a factor affecting a travel time of the transport vehicle and being higher for a longer travel time of the transport vehicle, and
the control system performs, in determining a travel path of the standby vehicle, a cost adjustment process in response to the battery level of the standby vehicle being less than a second set value, and the cost adjustment process comprises at least one of causing the cost of a path through the non-charging area to be higher than in a case of the battery level of the standby vehicle being greater than or equal to the second set value or causing the cost of a path through the charging area to be lower than in a case of the battery level of the standby vehicle being greater than or equal to the second set value.

3. The article transport facility according to claim 2, wherein:
the cost comprises at least one of:
a distance cost being higher for a greater distance by which the transport vehicle travels,
a structure cost being higher for a slower possible moving speed of the transport vehicle based on a structure of the travelable path,
a congestion cost being higher for longer congestion on the travel path of the transport vehicle, a greater number of transport vehicles involved in congestion on the travel path of the transport vehicle, or both, or
an other-vehicles cost being higher for a greater number of other transport vehicles on the travel path of the transport vehicle.

4. The article transport facility according to claim 1, wherein:
a transport vehicle, among the plurality of transport vehicles, in the first state is an operating vehicle, and
the control system determines the travel destination of the standby vehicle on a travel path of the operating vehicle.

5. The article transport facility according to claim 1, wherein:
the control system determines the travel destination of the standby vehicle in such a manner as to adjust the number of standby vehicles in each of a plurality of control areas defined by dividing a full portion of the travelable path so that the number of standby vehicles falls within a range set for the control area.

6. The article transport facility according to claim 1, wherein:
in response to the battery level of the standby vehicle being less than the set value while the standby vehicle is traveling to the travel destination in the non-charging area, the control system performs a destination change process of changing the travel destination of the standby vehicle to a position in the charging area.
